(19) United States
(12) Patent Application Publication
(10) Pub. No.: US 2022/0357535 A1
(43) Pub. Date: Nov. 10, 2022

(54) OPTO-ELECTRIC COMPOSITE TRANSMISSION MODULE

(71) Applicant: NITTO DENKO CORPORATION, Osaka (JP)

(72) Inventor: Kazuaki SUZUKI, Osaka (JP)

(73) Assignee: NITTO DENKO CORPORATION, Osaka (JP)

(21) Appl. No.: 17/624,488

(22) PCT Filed: Jul. 3, 2020
(86) PCT No.: PCT/JP2020/026231

§ 371 Date: Jan. 3, 2022

(30) Foreign Application Priority Data
Jul. 5, 2019 (JP) 2019-126116

(51) Int. Cl. G02B 6/42; H05K 1/02; H05K 1/18

(52) U.S. Cl. CPC G02B 6/4269; G02B 6/4281; G02B 6/4245; H05K 1/0274; H05K 1/189; H05K 2201/10121

(57) ABSTRACT

An opto-electric composite transmission module includes an opto-electric hybrid board, a printed wiring board, an opto-electric conversion portion, a first heat transfer member, and a case made of metal. The opto-electric hybrid board, the opto-electric conversion portion, the first heat transfer member, and a first wall of the case are disposed in order toward one side in a thickness direction. The printed wiring board integrally has a first portion and a second portion spaced apart from each other, and a connecting portion for connecting these when viewed from the top. The first portion, the second portion, and the connecting portion include a first overlapped region. The first overlapped region is overlapped with the opto-electric hybrid board without being overlapped with the opto-electric conversion portion when projected in the thickness direction. The first overlapped region is overlapped with the opto-electric conversion portion when projected in a plane direction.

### TECHNICAL FIELD

The present invention relates to an opto-electric composite transmission module.

### BACKGROUND ART

Conventionally, an optical module which includes a printed board, an optical waveguide, a FPC (printed wiring board), an opto-electric converter, a heat dissipation sheet, and a protrusion of a case in order toward one side in a thickness direction has been proposed (ref: for example, Patent Document 1 below). In Patent Document 1, by pressing the heat dissipation sheet downwardly by the protrusion of the case, the heat dissipation sheet is in tight contact with the opto-electric converter. In the optical module of Patent Document 1, heat generated from the opto-electric converter is dissipated toward the protrusion of the case through the heat dissipation sheet.

### CITATION LIST

### Patent Document

Patent Document 1: Japanese Unexamined Patent Publication No. 2015-22129

### SUMMARY OF THE INVENTION

### Problem to be Solved by the Invention

However, in the optical module of Patent Document 1, the opto-electric converter is overlapped with the printed board when projected in the thickness direction. The printed board is usually rigid, and rigidly supports the above-described opto-electric converter even when a flexible FPC is interposed between the printed board and the opto-electric converter. Then, the opto-electric converter is easily damaged by the above-described contact of the protrusion.

The present invention provides an opto-electric composite transmission module capable of suppressing damage to an opto-electric conversion portion, while efficiently dissipating heat of the opto-electric conversion portion.

### Means for Solving the Problem

The present invention (1) includes an opto-electric composite transmission module including an opto-electric hybrid board, a printed wiring board electrically connected to the opto-electric hybrid board, an opto-electric conversion portion optically and electrically connected to the opto-electric hybrid board, a heat transfer member adjacent to the opto-electric conversion portion in a thickness direction, and a case made of metal, accommodating the opto-electric hybrid board, the printed wiring board, the opto-electric conversion portion, and the heat transfer member, and including a first wall, wherein the opto-electric hybrid board, the opto-electric conversion portion, the heat transfer member, and the first wall are disposed in order toward one side in the thickness direction; the printed wiring board integrally has a first portion and a second portion spaced apart from each other, and a connecting portion connecting the first portion to the second portion when viewed from the top; the first portion, the second portion, and the connecting portion include a region which is overlapped with the opto-electric hybrid board without being overlapped with the opto-electric conversion portion when projected in the thickness direction, and is overlapped with the opto-electric conversion portion when projected in a direction perpendicular to the thickness direction.

In the opto-electric composite transmission module, since the opto-electric conversion portion, the heat transfer member, and the first wall are disposed in order toward one side in the thickness direction, it is possible to emit heat generated in the opto-electric conversion portion to the first wall through the heat transfer member.

Further, the region of the first portion, the second portion, and the connecting portion in the printed wiring board is overlapped with the opto-electric hybrid board without being overlapped with the opto-electric conversion portion, when projected in the thickness direction, so that even when the heat transfer member is brought into contact with the opto-electric conversion portion, and further, the heat transfer member pressurizes the opto-electric conversion portion, the opto-electric conversion portion can be flexibly supported by the opto-electric hybrid board from the other side in the thickness direction thereof. Therefore, it is possible to suppress damage to the opto-electric conversion portion.

Further, when projected in the direction perpendicular to the thickness direction, since the above-described region is overlapped with the opto-electric conversion portion, it is possible to furthermore suppress damage to the opto-electric conversion portion due to a collision of another member with the opto-electric conversion portion.

Therefore, the opto-electric composite transmission module can suppress damage to the opto-electric conversion portion, while efficiently dissipating the heat of the opto-electric conversion portion.

The present invention (2) includes the opts-electric composite transmission module described in (1), wherein the heat transfer member is integral with the first wall.

However, when the heat transfer member is different from the first wall, it is necessary to dispose an adhesive between them, and the thermal conductivity of the adhesive is usually low. Therefore, the heat dissipation properties from an adjacent portion to the first wall are low.

On the other hand, in the opto-electric composite transmission module, since the adjacent portion is integral with the first wall, it is not necessary to dispose the above-described adhesive. Therefore, the heat dissipation properties from the adjacent portion to the first wall are excellent.

The present invention (3) includes the opto-electric composite transmission module described in (1) or (2) further including a heat dissipation layer in contact with one surface in the thickness direction of the opto-electric conversion portion and the other surface in the thickness direction of the heat transfer member.

Since the opto-electric composite transmission module further includes the heat dissipation layer in contact with one surface in the thickness direction of the opto-electric conversion portion and the other surface in the thickness direction of the heat transfer member, it is possible to efficiently dissipate the heat from the opto-electric conversion portion to the heat transfer member through the heat dissipation layer.

The present invention (4) includes the opto-electric composite transmission module described in any one of (1) to (3) further including a second heat transfer member adjacent to the opposite side of the opto-electric conversion portion in the thickness direction with respect to the opto-electric hybrid board, wherein the case further includes a second wall disposed on the opposite side of the opto-electric hybrid board in the thickness direction with respect to the second heat transfer member, and thus, the opts-electric hybrid board, the second heat transfer member, and the second wall are disposed in order toward the other side in the thickness direction,

In the opto-electric composite transmission module, it is possible to emit the heat of the opto-electric conversion portion to the second wall through the opto-electric hybrid board and the second heat transfer member.

The present invention (5) includes the opto-electric composite transmission module described in (4), wherein the second heat transfer member is integral with the second wall.

However, when the second heat transfer member is different from the second wall, it is necessary to dispose an adhesive between them, and the thermal conductivity of the adhesive is usually low. Therefore, the heat dissipation properties from the second adjacent portion to the second wall are low.

On the other hand, in the opto-electric composite transmission module, since the second adjacent portion is integral with the second wall, it is not necessary to dispose the above-described adhesive. Therefore, the heat dissipation properties from the second adjacent portion to the second wall are excellent.

The present invention (6) includes the opto-electric composite transmission module described in (5) further including a second heat dissipation layer in contact with the other surface in the thickness direction of the opto-electric hybrid board and one surface in the thickness direction of the second heat transfer member.

Since the opto-electric composite transmission module further includes the second heat dissipation layer in contact with the other surface in the thickness direction of the opts-electric hybrid board and one surface in the thickness direction of the second heat transfer member, it is possible to efficiently dissipate the heat to the second heat transfer member through the second heat dissipation layer.

The present invention (7) includes the opto-electric composite transmission module described in (4), wherein the other surface in the thickness direction of the heat transfer member is in contact with one surface in the thickness direction of the opto-electric conversion portion, and the second heat transfer member is an elastic member.

Even when the other surface in the thickness direction of the heat transfer member is in contact with one surface in the thickness direction of the opto-electric conversion portion, since the second heat transfer member is the elastic member, by the second heat transfer member, it is possible to constantly hold the pressure which attempts to fluctuate due to a contact of the opto-electric conversion portion with the heat transfer member.

Therefore, the opto-electric composite transmission module can prevent damage to the opto-electric conversion portion.

The present invention (8) includes the opto-electric composite transmission module described in any one of (1) to (7), wherein the opto-electric hybrid board includes an electric circuit board, and the electric circuit board includes a metal support layer, an insulating layer, and a conductive layer in order in the thickness direction.

In the opto-electric composite transmission module, since the electric circuit board includes the metal support layer, the heal dissipation properties of the opto-electric conversion portion through the electric circuit board are excellent.

The present invention (9) includes the opto-electric composite transmission module described in (8), wherein the insulating layer has a through hole penetrating in the thickness direction and exposing one surface in the thickness direction of the metal support layer, and the opto-electric composite transmission module further includes a heat dissipation portion in contact with an inner peripheral surface of the through hole in the insulating layer, and one surface in the thickness direction of the metal support layer.

Since the opto-electric composite transmission module includes the heat dissipation portion, it is possible to emit the heat of the insulating layer to the metal support layer through the heat dissipation portion.

The present invention (10) includes the opto-electric composite transmission module described in any one of (1) to (9), wherein the printed wiring board has an opening portion surrounded by the region, and the opto-electric conversion portion is disposed in the opening portion.

In the opto-electric composite transmission module, since the above-described region in the printed wiring board is disposed around the opening portion, even when the opto-electric conversion portion is pressurized by the heat transfer member, the opts-electric hybrid board overlapped with the above-described region can flexibly and reliably support the opto-electric conversion portion.

Moreover, the periphery of the opto-electric conversion portion located in the opening portion of the printed wiring board is surrounded by the printed wiring board. Therefore, it is possible to furthermore suppress damage to the opto-electric conversion portion.

### Effect of the Invention

The opto-electric composite transmission module of the present invention can suppress damage to an opto-electric conversion portion, while efficiently dissipating heat of the opto-electric conversion portion.

### BRIEF DESCRIPTION OF THE DRAWINGS

FIGS. 1A to 1D show plan views and bottom views for illustrating an opto-electric composite transmission device including one embodiment of an opto-electric composite transmission module of the present invention:

FIG. 1A illustrating a plan view of the opto-electric composite transmission device,

FIG. 1B illustrating a bottom view of a lid of a case,

FIG. 1C illustrating a plan view of the opto-electric composite transmission device from which the lid is removed, and

FIG. 1D illustrating a bottom view of the opto-electric composite transmission device from which a main body of the case is removed.

FIG. 2 shows a side cross-sectional view of the opto-electric composite transmission device shown in FIG. 1A.

FIG. 3 shows an enlarged side cross-sectional view of the opto-electric composite transmission device shown in FIG. 2.

FIG. 4 shows a side cross-sectional view of a modified example (embodiment in which a first heat transfer member is different from a first wall) of the opto-electric composite transmission device shown in FIG. 2.

FIG. 5 shows a side cross-sectional view of a modified example (embodiment in which a second heat transfer member is provided) of the opto-electric composite transmission device shown in FIG. 2.

FIG. 6 shows a side cross-sectional view of a modified example (embodiment in which a first heat dissipation layer and a second heat dissipation layer are provided) of the opto-electric composite transmission device shown in FIG. 2.

FIG. 7 shows a side cross-sectional view of a modified example (embodiment in which an elastic member is provided) of the opto-electric composite transmission device shown in FIG. 2.

FIG. 8 shows a plan view of a modified example (embodiment in which a printed wiring board does not have a second portion) of the opto-electric composite transmission device shown in FIG. 1C.

### DESCRIPTION OF EMBODIMENTS

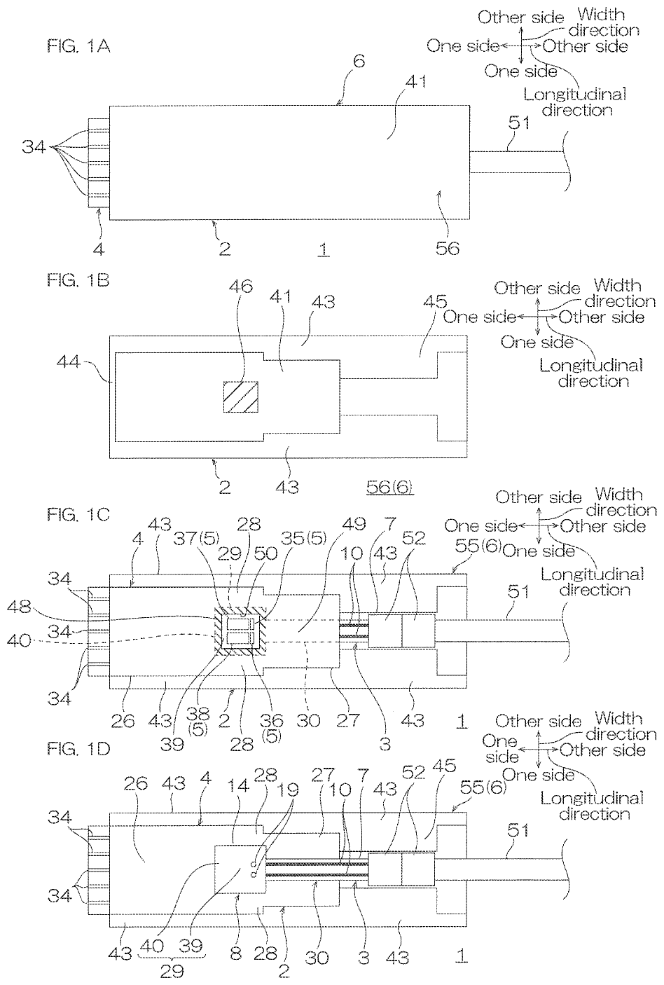

An opto-electric composite transmission device including one embodiment of an opto-electric composite transmission module of the present invention is described with reference to FIGS. 1A to 3. In FIG. 1B, in order to clearly show the relative arrangement and the shape of a first heat transfer member 46 (described later) with respect to a first wall 41 (described later), the first heat transfer member 46 is shown by hatching. Further, in FIG. 1C, in order to clearly show the relative arrangement and the shape of a first overlapped region 48 (described later), the first overlapped region 48 is shown by hatching.

As shown in FIGS. 1A and 1C, an opto-electric composite transmission device 1 includes an opto-electric composite transmission module 2, an optical fiber 51, and a connector 52.

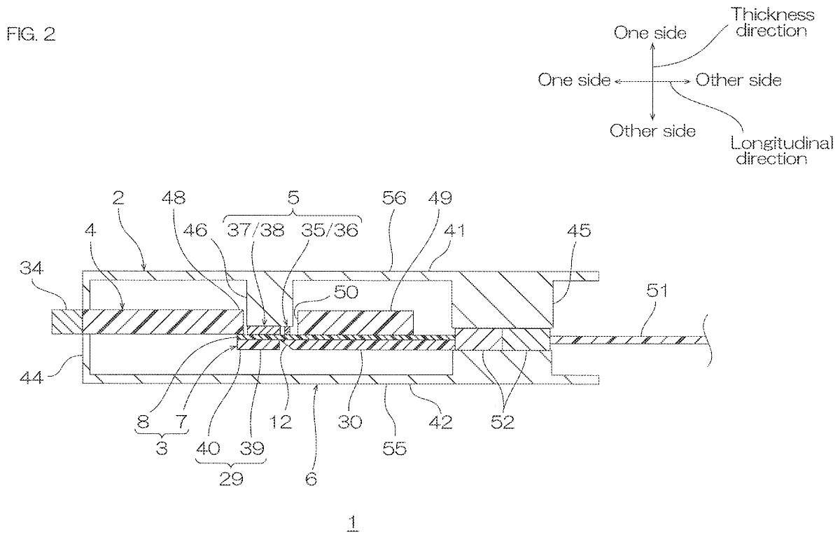

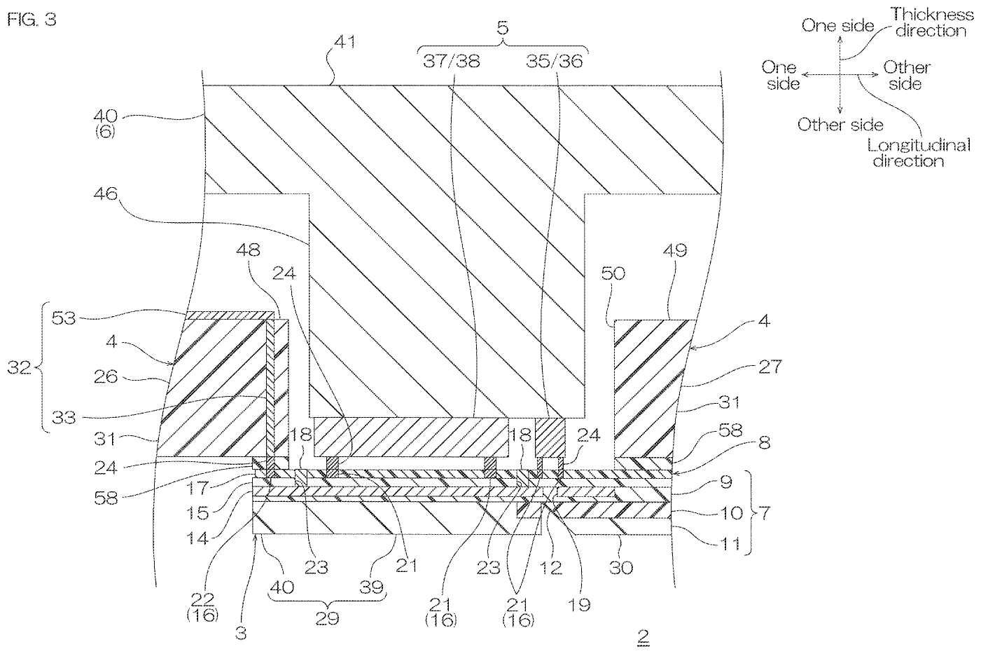

The opto-electric composite transmission module 2 converts light output from the optical fiber 51 into electricity to be input into an electrical device which is not shown, and converts the electricity output from the electrical device which is not shown into the light to be input into the optical fiber 51. The opto-electric composite transmission module 2 has a generally flat plate shape extending long along a flow direction of the light and the electricity described above. As shown in FIG. 2, the opto-electric composite transmission module 2 includes an opto-electric hybrid board 3, a printed wiring board 4, an opto-electric conversion portion 5, and a case 6.

As shown in FIG. 1D, the opto-electric hybrid board 3 has a generally flat plate shape extending long along a longitudinal direction of the opto-electric composite transmission module 2. The opto-electric hybrid board 3 has an opto-electric conversion region 29 and an optical transmission region 30 when viewed from the bottom.

The opto-electric conversion region 29 is disposed in one end portion in the longitudinal direction of the opto-electric hybrid board 3. The opto-electric conversion region 29 has a generally rectangular shape (specifically, square shape) when viewed from the bottom. As shown in FIGS. 1C (broken line), 1D, and 3, the opto-electric conversion region 29 includes a mounting region 39 for mounting the opto-electric conversion portion 5, and a second terminal forming region 40 including a region where a second terminal 22 (described later) is formed.

The mounting region 39 is disposed in a generally central portion when viewed from the bottom of the opto-electric conversion region 29.

The second terminal forming region 40 is disposed around the mounting region 39. The second terminal forming region 40 has a generally rectangular frame shape when viewed from the bottom.

The optical transmission region 30 has a generally rectangular shape when viewed from the bottom extending from the other end portion in the longitudinal direction of the opto-electric conversion region 29 toward the other side in the longitudinal direction. A width (length in a width direction (direction perpendicular to the longitudinal direction and a thickness direction)) of the optical transmission region 30 is narrower than that of the opto-electric conversion region 29. A length in the longitudinal direction of the optical transmission region 30 is longer than that in the longitudinal direction of the opto-electric conversion region 29.

As shown in FIG. 3, the optic-electric hybrid hoard 3 includes an optical waveguide 7 and an electric circuit board 8 in order toward one side in the thickness direction. Specifically, the opto-electric hybrid board 3 includes the optical waveguide 7, and the electric circuit board 8 disposed on one surface in the thickness direction of the optical waveguide 7.

The optical waveguide 7 is located in an other-side portion in the thickness direction of the opto-electric hybrid board 3. The optical waveguide 7 has a generally sheet shape extending in the longitudinal direction. The optical waveguide 7 includes an under clad layer 9, a core layer 10, and an over clad layer 11 in order toward the other side in the thickness direction. The over clad layer 11 covers the core layer 10. A mirror 12 is formed in one end portion in the longitudinal direction of the core layer 10. Examples of a material for the optical waveguide 7 include transparent materials such as an epoxy resin. A thickness of the optical waveguide 7 is, for example, 20 μm or more, and is, for example, 200 μm or less.

The electric circuit board 8 is located in a one-side portion in the thickness direction of the opto-electric hybrid board 3. The electric circuit board 8 is disposed on one surface in the thickness direction of the under clad layer 9. The electric circuit board 8 has a generally sheet shape extending in the longitudinal direction. The electric circuit board 8 includes a metal support layer 14, a base insulating layer 15 as one example of an insulating layer, a conductive layer 16, and a cover insulating layer 17 as one example of an insulating layer in order toward one side in the thickness direction. Also, the electric circuit board 8 further includes a heat dissipation portion 18.

As shown in FIGS. 1D and 3, the metal support layer 14 is disposed in the opto-electric conversion region 29. The metal support layer 14 has a metal opening portion 19 penetrating in the thickness direction. The plurality of metal opening portions 19, corresponding to a light emitting element 35 and a light receiving element 36 to be described later, are provided. Examples of a material for the metal support layer 14 include metals such as stainless steel, 42-alloy, aluminum, copper-beryllium, phosphor bronze, copper, silver, nickel, chromium, titanium, tantalum, platinum, and gold. A thickness of the metal support layer 14 is, for example, 3 μm or more, preferably 10 μm or more, and is, for example, 100 μm or less, preferably 50 μm or less.

The base insulating layer 15 is disposed over the opto-electric conversion region 29 and the optical transmission region 30. The base insulating layer 15 is disposed on one surface in the thickness direction of the metal support layer 14. Further, the base insulating layer 15 closes one end edge in the thickness direction of the metal opening portion 19. Examples of a material for the base insulating layer 15 include resins such as polyimide. The material for the base insulating layer 15 has light transmittance properties. A thickness of the base insulating layer 15 is, for example, 2 μm or more, and is 35 μm or less.

The conductive layer 16 is disposed on one side in the thickness direction of the base insulating layer 15. The conductive layer 16 is disposed in the opto-electric conversion region 29. The conductive layer 16 includes a first terminal 21, a second terminal 22, and a wiring which is not shown.

The first terminal 21 is disposed in the mounting region 39. The first terminal 21 is patterned corresponding to an electrode (not shown) of the opto-electric conversion portion 5.

The second terminal 22 is disposed in the second terminal forming region 40. The second terminal 22 is patterned corresponding to a via 33 of the printed wiring board 4.

A wiring which is not shown is disposed in the opto-electric conversion region 29 (the mounting region 39 and the second terminal forming region 40). The wiring which is not shown electrically connects the first terminal 21 to the second terminal 22.

Examples of a material for the conductive layer 16 include conductors such as copper. A thickness of the conductive layer 16 is, for example, 2 μm or more, and is 20 μm or less.

The cover insulating layer 17 is disposed on one surface in the thickness direction of the base insulating layer 15 so as to expose the first terminal 21 and the second terminal 22 and to cover the wiring which is not shown. The cover insulating layer 17 is disposed over the opto-electric conversion region 29 and the optical transmission region 30. A material and a thickness of the cover insulating layer 17 are the same as those of the base insulating layer 15.

Further, in the base insulating layer 15 and the cover insulating layer 17, a heat dissipation opening portion 23 as one example of a through hole penetrating them in the thickness direction is formed. The heat dissipation opening portion 23 is filled with the heat dissipation portion 18 to be described next. The heat dissipation opening portion 23 is disposed in the mounting region 39. Specifically, it is disposed in the base insulating layer 15 and the cover insulating layer 17 around a drive integrated circuit 37 and an impedance conversion amplifier circuit 38 (described later).

The heat dissipation portion 18 fills the heat dissipation opening portion 23. The heat dissipation portion 18 is disposed on one surface in the thickness direction of the metal support layer 14 exposed from the heat dissipation opening portion 23. Further, the heat dissipation portion 18 is in contact with one surface in the thickness direction of the metal support layer 14, and the inner peripheral surface of the heat dissipation opening portion 23 in the base insulating layer 15 and the cover insulating layer 17. Further, one surface in the thickness direction of the heat dissipation portion 18 is exposed from the cover insulating layer 17. Examples of a material for the heat dissipation portion 18 include metals and thermally conductive resin compositions (consisting of a thermally conductive filler and a resin), and preferably, a metal, specifically, the same metal as the conductive layer 16 is used. A thickness of the heat dissipation portion 18 is the total thickness of the base insulating layer 15 and the cover insulating layer 17, and is, for example, 5 μm or more, preferably 10 μm or more, and is, for example, 100 μm or less, preferably 50 μm or less. The plane area of the heat dissipation portion 18 is, for example, 0.1 mm² or more, preferably 1 mm² or more, more preferably 5 mm² or more, and is, for example, 1000 mm² or less. When the plane area of the heat dissipation portion 18 is the above-described lower limit or more, it is possible to improve the heat dissipation properties of the electric circuit board 8.

A thickness of the electric circuit board 8 is, for example, 20 μm or more, and is, for example, 200 μm or less. A ratio of the thickness of the metal support layer 14 to that of the electric circuit board 8 is, for example, 0.2 or more, preferably 0.4 or more, more preferably 0.6 or more, and is, for example, 0.9 or less. When the above-described ratio is the above-described lower limit or more, it is possible to improve the heal dissipation properties of the electric circuit board 8,

A thickness of the opto-electric hybrid board 3 is, for example, 25 μm or more, preferably 40 μm or more, and is, for example, 500 μm or less, preferably 250 μm or less. A ratio of the thickness of the metal support layer 14 to that of the opto-electric hybrid board 3 is, for example, 0.05 or more, preferably 0.1 or more, more preferably above 0.15 and is, for example, 0.4 or less. When the above-described ratio is above the above-described lower limit, it is possible to improve the heat dissipation properties of the opto-electric hybrid board 3.

The opto-electric hybrid board 3 is flexible, and specifically, a tensile elastic modulus at 25° C. of the opto-electric hybrid board 3 (the opto-electric conversion region 29 thereof) is, for example, below 10 GPa, preferably 5 GPa or less, and is, for example, 0.1 GPa or more. When the tensile elastic modulus of the opto-electric hybrid board 3 is below the above-described upper limit, it is possible to flexibly support the opto-electric conversion portion 5.

As shown in FIGS. 2 and 3, the printed wiring board 4 is disposed on one side in the thickness direction of the opto-electric hybrid board 3. The printed wiring board 4 has a generally flat plate shape extending long along the longitudinal direction. As shown in FIGS. 1C, 1D, and 3, the printed wiring board 4 integrally has a first portion 26, a second portion 27, and a connecting portion 28.

The first portion 26 is the one-side portion in the longitudinal direction of the printed wiring board 4.

The second portion 27 is oppositely disposed spaced apart from the other side in the longitudinal direction of the first portion 26. A width of the second portion 27 is narrower than that of the first portion 26.

The connecting portion 28 connects the first portion 26 to the second portion 27. Specifically, the two connecting portions 28 are provided. Of the two connecting portions 28, one connects one end portion in the width direction of the other end edge in the longitudinal direction of the first portion 26 to one end portion in the width direction of one end edge in the longitudinal direction of the second portion 27. Of the two connecting portions 28, the other connects the other end portion in the width direction of the other end edge in the longitudinal direction of the first portion 26 to the other end portion in the width direction of one end edge in the longitudinal direction of the second portion 27.

An opening portion 50 is divided by the first portion 26, the second portion 27, and the connecting portion 28 described above. The opening portion 50 is divided as a through hole penetrating the printed wiring board 4 in the thickness direction.

The printed wiring board 4 includes the first overlapped region 48 which is overlapped with the second terminal forming region 40 of the opto-electric hybrid board 3, and a second overlapped region 49 which is overlapped with the optical transmission region 30 of the opto-electric hybrid board 3 when projected in the thickness direction. Further, the opening portion 50 of the printed wiring board 4 corresponds to the mounting region 39 of the opto-electric hybrid board 3, and specifically, exposes the mounting region 39.

The first overlapped region 48 is one example of a region which is overlapped with the opto-electric hybrid board 3. The first overlapped region 48 is included in the first portion 26, the second portion 27, and the connecting portion 28. Specifically, the first overlapped region 48 is divided over an intermediate portion in the width direction of the other end portion in the longitudinal direction of the first portion 26, the intermediate portion in the width direction of one end portion in the longitudinal direction of the second portion 27, and inner-side portions of the two connecting portions 28. On the other hand, the first overlapped region 48 is not overlapped with the mounting region 39 of the opto-electric hybrid board 3 when projected in the thickness direction. Therefore, the first overlapped region 48 is not overlapped with the opto-electric conversion portion 5 (described later) mounted on the mounting region 39 when projected in the thickness direction. Since the opening portion 50 has a generally rectangular shape when viewed from the top, the first overlapped region 48 has a generally endless frame shape surrounding the periphery of the opening portion 50 when viewed from the top.

The second overlapped region 49 is continuously formed on the other side in the longitudinal direction of the first overlapped region 48.

The printed wiring board 4 includes a support board 31 and a conductive circuit 32.

The support board 31 extends in the longitudinal direction, and includes the first overlapped region 48 and the second overlapped region 49. Examples of a material for the support board 31 include hard materials such as a glass fiber reinforced epoxy resin. A tensile elastic modulus at 25° C. of the support board 31 is, for example, 10 GPa or more, preferably 15 GPa or more, more preferably 20 GPa or more, and is, for example, 1000 GPa or less. When the tensile elastic modulus of the support board 31 is the above-described lower limit or more, the mechanical strength of the printed wiring board 4 is excellent.

As shown in FIGS. 1C and 3, the conductive circuit 32 includes the via 33 (ref: FIG. 3), a third terminal 34 (ref: FIG. 1C), and a wiring 53 (ref: FIG. 3) when projected in the thickness direction.

The via 33 penetrates the support board 31 in the thickness direction. The other surface in the thickness direction of the via 33 is exposed from the support board 31, and functions as a terminal. The other surface in the thickness direction of the via 33 is electrically connected to the second terminal 22 through a bump 24. Thus, the printed wiring board 4 is electrically connected to the opto-electric hybrid board 3.

The third terminal 34 is disposed in one end portion in the longitudinal direction of the first portion 26 of the printed wiring board 4.

The wiring 53 is disposed on one surface in the thickness direction of the support board 31. The wiring 53 electrically connects the via 33 to the third terminal 34.

A thickness of the printed wiring board 4 is greater than that of the opto-electric hybrid board 3, and specifically, is, 100 μm or more, preferably 500 μm or more, more preferably 1,000 μm or more, and is, for example, 10,000 μm or less. A ratio of the thickness of the printed wiring board 4 to that of the opto-electric hybrid board 3 is, for example, 0.01 or more, preferably 0.05 or more, more preferably 0.1 or more, and is, for example, 0.25 or less. When the above-described ratio is the above-described lower limit or more, the printed wiring board 4 in the opto-electric hybrid board 3 is thickened, and it is possible to flexibly support the opto-electric conversion portion 5 in the opening portion 50 by the thin opto-electric hybrid board 3, while ensuring the rigidity of the opto-electric hybrid board 3.

The opto-electric conversion portion 5 is mounted on the mounting region 39 of the opto-electric hybrid hoard 3. The opto-electric conversion portion 5 has an electrode (not shown) on the other surface in the thickness direction. The electrode of the opto-electric conversion portion 5 is electrically connected to the first terminal 21 of the opto-electric hybrid board 3 through the bump 24. Thus, the opto-electric conversion portion 5 is flip-chip (face-down) mounted on the electric circuit board 8 of the opto-electric hybrid board 3. Thus, the opto-electric conversion portion 5 is electrically connected to the opto-electric hybrid board 3. The opto-electric conversion portion 5 is electrically connected to the conductive circuit 32 of the printed wiring board 4 through the conductive layer 16 of the opto-electric hybrid board 3.

Since the opto-electric conversion portion 5 is mourned on the mounting region 39, as described above, it is not overlapped with the first overlapped region 48 when projected in the thickness direction.

On the other hand, the opto-electric conversion portion 5 is overlapped with the first overlapped region 48 when projected in a plane direction. Specifically, the opto-electric conversion portion 5 is included in the opening portion 50 of the printed wiring board 4 when projected in the plane direction. The opto-electric conversion portion 5 faces the inner peripheral surface of the opening portion 50 in the printed wiring board 4 in the plane direction. More specifically, the opto-electric conversion portion 5 is disposed spaced apart from the inner peripheral surface of the opening portion 50 in the opening portion 50 of the printed wiring board 4.

As shown in FIG. 1C, the opto-electric conversion portion 5 includes, for example, the light emitting element 35, the light receiving element 36, the drive integrated circuit (drive IC) 37, and the impedance conversion amplifier circuit (TIA) 38. The light emitting element 35, the light receiving element 36, the drive integrated circuit 37, and the impedance conversion amplifier circuit 38 are disposed in alignment at spaced intervals to each other in the plane direction.

The light emitting element 35 converts electricity into light. A light emitting port (not shown) of the light emitting element 35 is disposed on the other surface in the thickness direction of the light emitting element 35. Specific examples of the light emitting element 35 include surface emitting light emitting diodes (VECSEL).

The drive integrated circuit 37 is electrically connected to the light emitting element 35 through the conductive layer 16. The drive integrated circuit 37 is disposed in the vicinity of the light emitting element 35. The drive integrated circuit 37 drives the light emitting element 35.

The light receiving element 36 converts light into electricity. A light receiving port (not shown) of the light receiving element 36 is disposed on the other surface in the thickness direction of the light receiving element 36. Specific examples of the light receiving element 36 include photodiodes (PD).

The impedance conversion amplifier circuit 38 is electrically connected to the light receiving element 36 through the conductive layer 16. The impedance conversion amplifier circuit 38 is disposed in the vicinity of the light receiving element 36. The impedance conversion amplifier circuit 38 amplifies the electricity of the light receiving element 36.

Each of the light emitting port of the light emitting element 35, and the light receiving port of the light receiving element 36 faces the mirror 12 in the thickness direction. Thus, the light emitting element 35 and the light receiving element 36 are optically connected to the optical waveguide 7.

In the opto-electric conversion portion 5, the electricity input from the printed wiring board 4 into the light emitting element 35 is converted into light by the light emitting element 35 driven by the drive integrated circuit 37, and the resulting light is emitted toward the mirror 12 of the optical waveguide 7. Further, in the opto-electric conversion portion 5, the light input from the mirror 12 of the optical waveguide 7 into the light receiving element 36 is converted into the electricity by the light receiving element 36, and the resulting electricity is amplified by the impedance conversion amplifier circuit 38 to be input into the printed wiring board 4.

Therefore, the opto-electric conversion portion 5 is capable of mutually converting electricity and light.

As shown in FIGS. 1C and 2, the case 6 has a generally box shape for accommodating the opto-electric hybrid board 3, the printed wiring board 4, and the opto-electric conversion portion 5 (excluding the third terminal 34). Specifically, the case 6 has a generally flat box shape extending in the longitudinal direction, and in which the length thereof in the thickness direction is smaller than that in the width direction.

The case 6 is made of metal. Specific examples of the metal material for the case 6 include aluminum, copper, silver, zinc, nickel, chromium, titanium, tantalum, platinum, gold, and alloys of these (red copper, stainless steel, and the like). The case 6 may he subjected to surface treatment such as plating.

The case 6 integrally includes the first wall 41, a second wall 42, both side walls 43, a longitudinal directional one side wall 44, and a longitudinal directional other side wall 45.

The first wall 41 has a generally flat plate shape extending in the longitudinal direction.

The second wall 42 is spaced apart from the first wall 41 at the other side in the thickness direction. The second wall 42 has the same shape as the first wall 41.

One of the both side walls 43 connects one end portion in the width direction of the first wall 41 to one end portion in the width direction of the second wall 42 in the thickness direction. The other of the both side walls 43 connects the other end portion in the width direction of the first wall 41 to the other end portion in the width direction of the second wall 42 in the thickness direction.

The longitudinal directional one side wall 44 connects one end portion in the longitudinal direction of the first wall 41, the second wall 42, and the both side walls 43. However, the longitudinal directional one side wall 44 has a hole in which the third terminal 34 is disposed.

The longitudinal directional other side wall 45 connects the other end portion in the longitudinal direction of the first wall 41, the second wall 42, and the both side walls 43. However, the longitudinal directional other side wall 45 has a hole in which the connector 52 is disposed.

As shown in FIG. 2, the case 6 is obtained by assembling a lid 56 including the above-described first wall 41, and a main body 55 including the second wall 42. Each of the both side walls 43 is included in both the lid 56 and the main body 55. The longitudinal directional one side wall 44 is included in both the lid 56 and the main body 55. The longitudinal directional other side wall 45 is included in both the lid 56 and the main body 55.

Then, the optic-electric composite transmission module 2 includes the first heat transfer member 46 as one example of a heat transfer member. The first heat transfer member 46 is adjacent to one side in the thickness direction with respect to the opto-electric conversion portion 5. More specifically, the first heat transfer member 46 is interposed between the opto-electric conversion portion 5 and the first wall 41. Further, the other surface in the thickness direction of the first heat transfer member 46 is in contact with each entire one surface in the thickness direction of the light emitting element 35, the light receiving element 36, the drive integrated circuit 37, and the impedance conversion amplifier circuit 38.

Furthermore, the first heat transfer member 46 is integral with the first wall 41. The first heat transfer member 46 protrudes from the other surface in the thickness direction of the first wall 41 toward the opto-electric conversion portion 5. Examples of a material for the first heat transfer member 46 include metal materials illustrated in the case 6.

The opto-electric hybrid board 3 (the mounting region 39). the opto-electric conversion portion 5, the first heat transfer member 46, and the first wall 41 are disposed (laminated) in the above-described direction in the opening portion 50 of the printed wiring board 4, that is, are not overlapped with the printed wiring board 4 when projected in the thickness direction.

The first heat transfer member 46, together with the opto-electric hybrid board 3, the printed wiring board 4, and the opto-electric conversion portion 5, is accommodated in the case 6.

The first heat transfer member 46 has a generally thick flat plate shape. The first heat transfer member 46 is included in the opening portion 50 when projected in the thickness direction. Further, the other-side portion in the thickness direction of the first heat transfer member 46 is disposed in the opening portion 50.

A ratio of the plane cross-sectional area of the first heat transfer member 46 to the opening area of the opening portion 50 is, for example, 0.5 or more, preferably 0.7 or more, more preferably 0.9 or more, and is, for example, 0.99 or less, preferably 0.95 or less. When the above-described ratio is the above-described lower limit or more, the heat dissipation properties through the first heat transfer member 46 are excellent. When the above-described ratio is the above-described upper limit or less, it is possible to smoothly enter the other-side portion in the thickness direction of the first heat transfer member 46 into the opening portion 50.

One end surface in the longitudinal direction of the optical fiber 51 is optically connected to the other end surface in the longitudinal direction of the optical waveguide 7 of the opto-electric hybrid hoard 3 through the connector 52. The connector 52 is accommodated in a hole in the longitudinal directional other side wall 45.

To obtain the opto-electric composite transmission device 1, the opto-electric conversion portion 5 is mounted on the opto-electric hybrid board 3, and the printed wiring board 4 is bonded to the opto-electric hybrid board 3 through an adhesive 58. Thus, the opto-electric conversion portion 5 is disposed in the opening portion 50 of the printed wiring board 4. Further, the optical waveguide 7 of the opto-electric hybrid board 3 is connected to the optical fiber 51 through the connector 52.

Thereafter, the opto-electric hybrid board 3, the printed wiring board 4, and the opto-electric conversion portion 5 are disposed in the main body 55 of the case 6. Thereafter, the lid 56 is adjusted to the main body 55 so that the other-side portion in the thickness direction of the first heat transfer member 46 is inserted into the opening portion 50, and the other surface in the thickness direction of the first heat transfer member 46 is in contact with each opto-electric conversion portion 5. At this time, the first heat transfer member 46 is allowed to pressurize the opto-electric conversion portion 5. Thus, the main body 55 and the lid 56 are assembled to form the case 6.

Thus, the opto-electric composite transmission device 1 is obtained.

Thereafter, when the opto-electric composite transmission device 1 is used, the third terminal 34 of the opto-electric composite transmission device 1 is inserted into an insertion port of an electrical device which is not shown.

Next, the conversion of electricity into light in the opto-electric composite transmission device 1 is described. The electricity flows from an electrical device which is not shown through the conductive circuit 32 of the printed wiring board 4, and is further input into the light emitting element 35 and the drive integrated circuit 37 through the conductive layer 16. The light emitting element 35 emits the light from the light emitting port toward the mirror 12 based on a drive force of the drive integrated circuit 37. Then, the optical path of the light is converted by the mirror 12, and the light travels through the optical waveguide 7 toward the other side in the longitudinal direction. Thereafter, the light is input from the optical waveguide 7 into the optical fiber 51.

Subsequently, the conversion of the light into the electricity in the opto-electric composite transmission device 1 is described. The light flows through the optical waveguide 7 from the optical fiber 51, and the optical path of the light is converted by the mirror 12 to be converted into the electricity by the light receiving element 36. On the other hand, the impedance conversion amplifier circuit 38 amplifies the electricity converted by the light receiving element 36 based on the electricity (electric power) supplied from the printed wiring board 4. The amplified electricity flows through the conductive circuit 32 of the printed wiring board 4 through the conductive layer 16 to be input into an electrical device which is not shown.

The opto-electric conversion portion 5 generates heat by the mutual conversion of the electricity and the light of the opto-electric conversion portion 5 described above. However, in the opto-electric composite transmission device 1, the heat of the opto-electric conversion portion 5 is emitted from the first wall 41 to the outside through the first heat transfer member 46.

In particular, a high electric current flows and a high voltage is applied in the drive integrated circuit 37 and the impedance conversion amplifier circuit 38. Therefore, the heating value of the drive integrated circuit 37 and the impedance conversion amplifier circuit 38 is high. However, in the drive integrated circuit 37 and the impedance conversion amplifier circuit 38, in addition to the above-described heat dissipation from the first heat transfer member 46, the heat transferred through the base insulating layer 15 and the cover insulating layer 17 which are adjacent to the drive integrated circuit 37 and the impedance conversion amplifier circuit 38 can be dissipated from the metal support layer 14 through the heat dissipation portion 18.

<Function and Effect of One Embodiment>

Then, in the opto-electric composite transmission module 2, since the opto-electric conversion portion 5, the first heat transfer member 46, and the first wall 41 are disposed in order toward one side in the thickness direction, the heat generated in the opto-electric conversion portion 5 can be emitted to the first wall 41 through the first heat transfer member 46.

Further, the first overlapped region 48 in the printed wiring board 4 is overlapped with the opto-electric hybrid board 3 without being overlapped with the opto-electric conversion portion 5 when projected in the thickness direction. Therefore, the first heat transfer member 46 is brought into contact with the opto-electric conversion portion 5, further, the first heat transfer member 46 pressurizes the opto-electric conversion portion 5, and the opto-electric conversion portion 5 can be flexibly supported (can be flexibly received) by the opto-electric hybrid board 3 from the other side in the thickness direction thereof. Therefore, it is possible to suppress damage to the opto-electric conversion portion 5.

Further, when projected in the plane direction, since the first overlapped region 48 of the opto-electric hybrid board 3 is overlapped with the opto-electric conversion portion 5, it is possible to furthermore suppress damage to the opto-electric conversion portion 5 due to a contact of another member from one side in the thickness direction with the first overlapped region 48, in particular, the first overlapped region 48 before the first heat transfer member 46 is disposed.

Therefore, the opto-electric composite transmission module 2 can suppress damage to the opto-electric conversion portion 5, while efficiently dissipating the heat of the opto-electric conversion portion 5.

In the opto-electric composite transmission module 2, since the electric circuit board 8 includes the metal support layer 14, the heat dissipation properties of the opto-electric conversion portion 5 through the electric circuit board 8 are excellent.

Furthermore, since the opto-electric composite transmission module 2 includes the heat dissipation portion 18, it is possible to emit the heat generated in the drive integrated circuit 37 and the impedance conversion amplifier circuit 38, and conducted to the base insulating layer 15 and the cover insulating layer 17 to the metal support layer 14 through the heat dissipation portion 18.

### MODIFIED EXAMPLES

In each modified example below, the same reference numerals are provided for members and steps corresponding to each of those in the above-described one embodiment, and their detailed description is omitted. Each modified example can achieve the same function and effect as that of one embodiment unless otherwise specified. Furthermore, one embodiment and the modified example thereof can be appropriately used in combination.

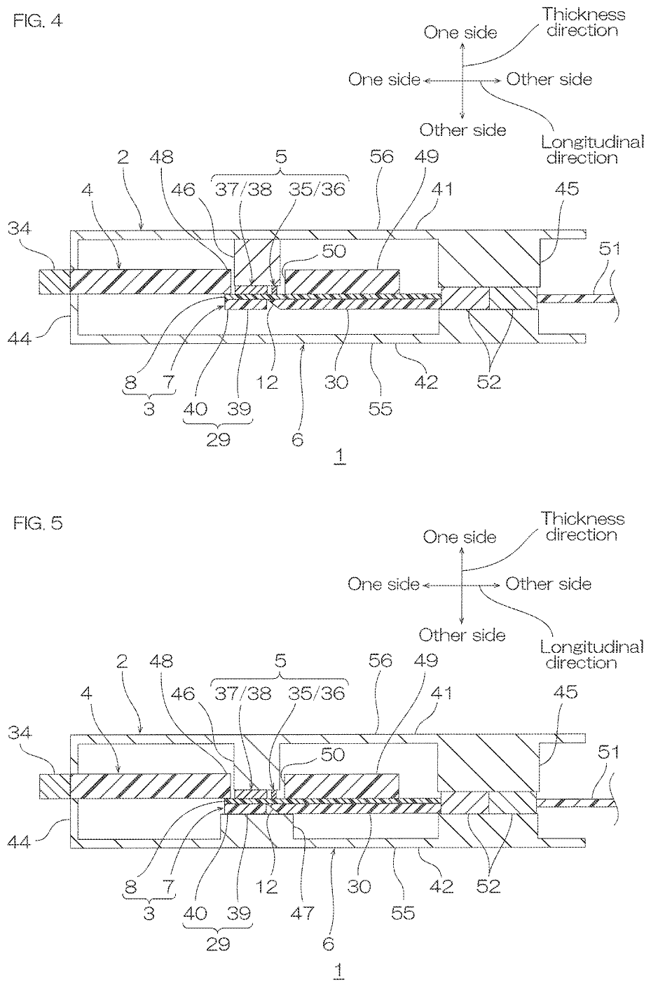

In the modified example shown in FIG. 4, the first heat transfer member 46 is different from the first wall 41. Examples of a material for the first heat transfer member 46 include thermally conductive resin compositions in addition to the above-described metal and, preferably, the metal is used. The first heat transfer member 46 is fixed to the other surface in the thickness direction of the first wall 41 through an adhesive which is not shown.

One embodiment shown in FIGS. 1A to 3 is more preferable than the modified example shown in FIG. 4. In the modified example shown in FIG. 4, the thermal conductivity of the adhesive is lower than that of the first wall 41 and the first heat transfer member 46. Therefore, the heat dissipation properties from the first heat transfer member 46 to the first wall 41 are low. On the other hand, in the opto-electric composite transmission module 2 of one embodiment, since the first heat transfer member 46 is integral with the first wall 41, it is not necessary to dispose the above-described adhesive. Therefore, the heat dissipation properties from the first heat transfer member 46 to the first wall 41 are excellent. Since the first heat transfer member 46 is integral with the first wall 41, and furthermore, there is no adhesive, it is possible to reduce the number of components, and the configuration is simple.

In the modified example shown in FIG. 5, the opto-electric composite transmission module 2 further includes a second heat transfer member 47 adjacent to the opposite side of the opto-electric conversion portion 5 in the thickness direction with respect to the opto-electric hybrid board 3. The second wall 42 is disposed on the opposite side of the opto-electric hybrid board 3 in the thickness direction with respect to the second heat transfer member 47.

One surface in the thickness direction of the second heat transfer member 47 is in contact with the other surface in the thickness direction of the optical waveguide 7. In the opto-electric composite transmission module 2, the opto-electric hybrid board 3, the second heat transfer member 47, and the second wall 42 are disposed in order toward the other side in the thickness direction. The second heat transfer member 47, together with the opto-electric hybrid board 3, the primed wiring board 4, the opto-electric conversion portion 5, and the first heat transfer member 46, is accommodated in the case 6.

The second heat transfer member 47 is integral with the second wall 42. The second heat transfer member 47 protrudes from one surface in the thickness direction of the second wall 42 toward the opto-electric hybrid board 3. Examples of a material for the second heat transfer member 47 include metal materials illustrated in the case 6.

The second heat transfer member 47 has a generally thick flat plate shape. The second heat transfer member 47 includes the opening portion 50 when projected in the thickness direction. Specifically, the second heat transfer member 47 is overlapped with the second terminal forming region 40 of the opto-electric hybrid board 3 when projected in the thickness direction. The second heat transfer member 47 has the plane area wider than that of the first heat transfer member 46.

According to the modified example, it is possible to emit the heat of the opto-electric conversion portion 5 to the second wall 42 through the opto-electric hybrid board 3 and the second heat transfer member 47.

On the other hand, though not shown, the second heat transfer member 47 may be different from the second wall 42. The second heat transfer member 47 is fixed to one surface in the thickness direction of the second wall 42 through an adhesive which is not shown.

Preferably, the second heat transfer member 47 is integral with the second wall 42. When the second heat transfer member 47 is integral with the second wall 42, it is not necessary to dispose the above-described adhesive. Therefore, the heat dissipation properties from the second heat transfer member 47 to the second wall 42 are excellent. Since the second heat transfer member 47 is integral with the second wall 42, and further, there is no adhesive, it is possible to reduce the number of components, and the configuration is simple.

Although not shown, the second heat transfer member 47 can have the plane area narrower than that of the first heat transfer member 46, and also can have the same plane area as that of the first heat transfer member 46. Even in such a modified example, the first heat transfer member 46 is included in the opening portion 50 when projected in the thickness direction.

The opto-electric hybrid board 3 is interposed between the second heat transfer member 47 and the opto-electric conversion portion 5, while the first heat transfer member 46 is in direct contact with the opto-electric conversion portion 5.

In the modified example shown in FIG. 6, the opto-electric composite transmission module 2 further includes a first heat dissipation layer 63 and a second heat dissipation layer 64.

The first heat dissipation layer 63 is interposed between the first heat transfer member 46 and the opto-electric conversion portion 5. The first heat dissipation layer 63 is disposed on the entire other surface in the thickness direction of the first heat transfer member 46. The first heat dissipation layer 63 is in contact with one surface in the thickness direction of the opto-electric conversion portion 5, and the other surface in the thickness direction of the first heat transfer member 46. Examples of the first heat dissipation layer 63 include heat dissipation sheets, heat dissipation grease, and heat dissipation plates. Examples of a material for the heat dissipation sheet include filler resin compositions in which a filler such as alumina (aluminum oxide), boron nitride, zinc oxide, aluminum hydroxide, fused silica, magnesium oxide, and aluminum nitride is dispersed in a resin such as a silicone resin, an epoxy resin, an acrylic resin, and a urethane resin. In the heat dissipation sheet, for example, the filler may be orientated in the thickness direction with respect to the resin. Also, the resin includes a thermosetting resin in a B-stage or a C-stage state. Further, the resin may include a thermoplastic resin.

The second heat dissipation layer 64 is interposed between the second heat transfer member 47 and the opto-electric, hybrid board 3. The second heat dissipation layer 64 is disposed on the entire one surface in the thickness direction of the second heat transfer member 47. The second heat dissipation layer 64 is in contact with the other surface in the thickness direction of the opto-electric conversion region 29 of the opto-electric hybrid board 3, and one surface in the thickness direction of the second heat transfer member 47. A material for the second heat dissipation layer 64 is the same as that for the first heat dissipation layer 63.

Since the modified example shown in FIG. 6 further includes the first heat dissipation layer 63, it is possible to efficiently dissipate the heat from the opto-electric conversion portion 5 to the first heat transfer member 46 through the first heat dissipation layer 63.

In addition, since the modified example shown in FIG. 6 further includes the second heat dissipation layer 64, it is possible to efficiently dissipate the heat from the opto-electric conversion region 29 of the opto-electric hybrid board 3 to the second wall 42 through the second heat dissipation layer 64 and the second heat transfer member 47.

Although not shown, the opto-electric composite transmission module 2 may also include only one of the first heat dissipation layer 63 and the second heat dissipation layer 64.

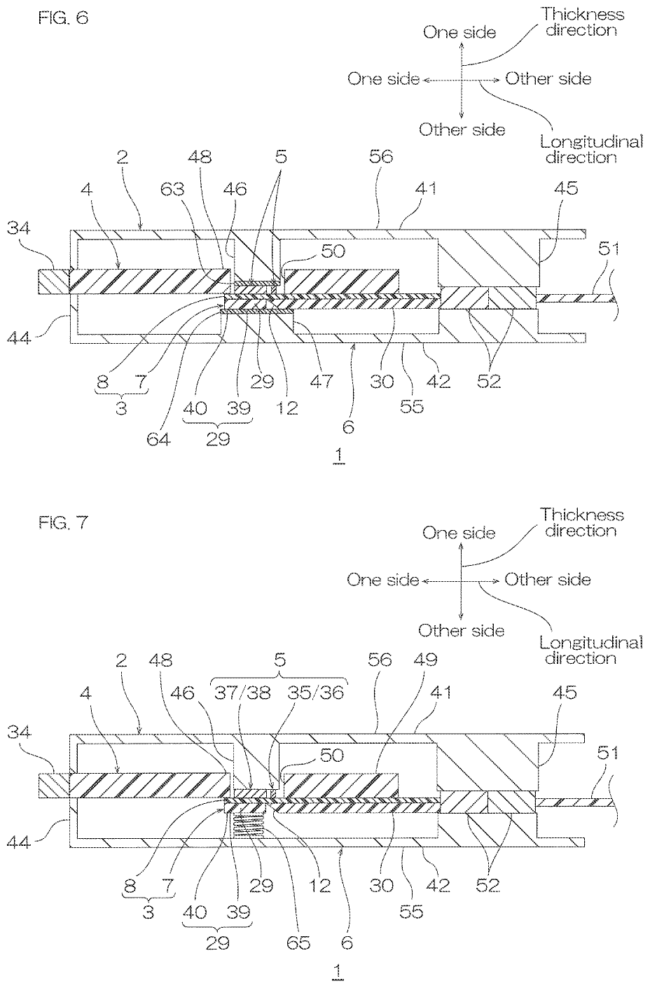

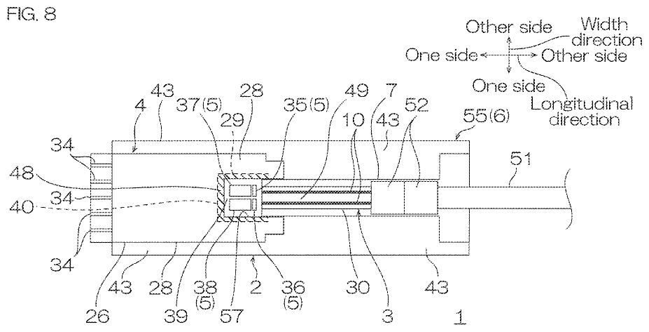

In the modified example shown in FIG. 7, in the opto-electric composite transmission module the second heat transfer member 47 is not integral with the first wall 41 and different therefrom, and furthermore, can be referred to as an elastic member 65.

The elastic member 65 is disposed between the mounting region 39 of the opts-electric hybrid board 3 and the second wall 42. The elastic member 65 is disposed on one surface in the thickness direction of the second wall 42 so as to be able to press the mounting region 39 of the opts-electric hybrid board 3 toward one side in the thickness direction. A material for the elastic member 65 is not particularly limited, and examples thereof include the same metal materials as those for the case 6 and thermally conductive polymer materials.

In the modified example, as in one embodiment, the other surface in the thickness direction of the first heat transfer member 46 is in contact with one surface in the thickness direction of the opto-electric conversion portion 5.

Then, in the modified example shown in FIG. 7, even when the other surface in the thickness direction of the first heat transfer member 46 is in contact with one surface in the thickness direction of the opts-electric conversion portion 5, and furthermore, the first heat transfer member 46 pressurizes the opto-electric conversion portion 5, since the second heat transfer member is the elastic member 65, by the elastic member 65, it is possible to constantly hold the pressure which attempts to fluctuate due to a contact of the opto-electric conversion portion 5 with the first heat transfer member 46.

Therefore, the opto-electric composite transmission module 2 can prevent damage to the opto-electric conversion portion 5, while having excellent heat dissipation properties of the opto-electric conversion portion 5.

As shown in FIG. 8, the printed wiring board 4 may not have the second portion 27, and has a cut-out portion 57 which is cut out from the other end surface in the width direction of the printed wiring board 4 toward one side (the first portion 26). The first overlapped region 48 has a generally U-shape having an end located around the cut-out portion 57 when viewed from the top.

Preferably, as in one embodiment, the printed wiring board 4 has the second portion 27 and the opening portion 50 is formed. In one embodiment, since the first overlapped region 48 in the printed wiring board 4 is disposed around the opening portion 50, even when the opto-electric conversion portion 5 is pressurized by the first heat transfer member 46, the opto-electric hybrid board 3 which is overlapped with the first overlapped region 48 can flexibly and reliably support the opto-electric conversion portion 5.

Moreover, the periphery of the opto-electric conversion portion 5 located in the opening portion 50 of the printed wiring board 4 is surrounded by the printed wiring board 4. Therefore, it is possible to furthermore suppress damage to the opto-electric conversion portion.

Furthermore, since in the printed wiring board 4, the two connecting portions 28 connect the first portion 26 to the second portion 27, the mechanical strength is excellent, and furthermore, the mechanical strength of the opto-electric composite transmission module 2 is excellent.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The opto-electric composite transmission module of the present invention is used for various applications.

### DESCRIPTION OF REFERENCE NUMERALS

1 Opto-electric composite transmission device

2 Opto-electric composite transmission module

3 Opto-electric hybrid board

4 Printed wiring board

5 Opto-electric conversion portion

6 Case

7 Optical waveguide

14 Metal support layer

18 Heat dissipation portion

23 Heat dissipation opening portion

26 First portion

27 Second portion

28 Connecting portion

41 First wall

42 Second wall

46 First heat transfer member

47 Second heat transfer member

48 First overlapped region

50 Opening portion

63 First heat dissipation layer

64 Second heat dissipation layer

65 Elastic member

1. An opto-electric composite transmission module comprising:
an opto-electric hybrid board,
a printed wiring board electrically connected to the opto-electric hybrid board,
an opto-electric conversion portion optically and electrically connected to the opto-electric hybrid board,
a heat transfer member adjacent to the opto-electric conversion portion in a thickness direction, and
a case made of metal, accommodating the opto-electric hybrid board, the printed wiring board, the opto-electric conversion portion, and the heat transfer member, and including a first wall, wherein
the opto-electric hybrid board, the opto-electric conversion portion, the heat transfer member, and the first wall are disposed in order toward one side in the thickness direction;
the printed wiring hoard integrally has a first portion and a second portion spaced apart from each other and
a connecting portion connecting the first portion to the second portion when viewed from the top;
the first portion, the second portion, and the connecting portion include a region which is overlapped with the opto-electric hybrid board without being overlapped with the opto-electric conversion portion when projected in the thickness direction, and
the region is overlapped with the opto-electric conversion portion when projected in a direction perpendicular to the thickness direction.

2. The opto-electric composite transmission module according to claim 1, wherein
the heat transfer member is integral with the first wall.

3. The opto-electric composite transmission module according to claim 1 further comprising:
a heat dissipation layer in contact with one surface in the thickness direction of the opto-electric conversion portion and the other surface in the thickness direction of the heat transfer member.

4. The opto-electric composite transmission module according to claim 1 further comprising:
a second heat transfer member adjacent to the opposite side of the opto-electric conversion portion in the thickness direction with respect to the opto-electric hybrid board, wherein
the case further includes a second wall disposed on the opposite side of the opto-electric hybrid board in the thickness direction with respect to the second heat transfer member, and thus,
the opto-electric hybrid board, the second heat transfer member, and the second wall are disposed in order toward the other side in the thickness direction.

5. The opto-electric composite transmission module according to claim 4, wherein
the second heat transfer member is integral with the second wall.

6. The opto-electric composite transmission module according to claim 5 further comprising:
a second heat dissipation layer in contact with the other surface in the thickness direction of the opto-electric hybrid board and one surface in the thickness direction of the second heat transfer member.

7. The opto-electric composite transmission module according to claim 4, wherein
the other surface in the thickness direction of the heat transfer member is in contact with one surface in the thickness direction of the opto-electric conversion portion, and
the second heat transfer member is an elastic member.

8. The opto-electric composite transmission module according to claim 1, wherein
the opto-electric hybrid board includes an electric circuit board, and
the electric circuit board includes a metal support layer, an insulating layer, and a conductive layer in order in the thickness direction.

9. The opto-electric composite transmission module according to claim 8, wherein
the insulating layer has a through hole penetrating in the thickness direction and exposing one surface in the thickness direction of the metal support layer, and
the opto-electric composite transmission module further includes a heat dissipation portion in contact with an inner peripheral surface of the through hole in the insulating layer, and one surface in the thickness direction of the metal support layer.

10. The opto-electric composite transmission module according to claim 1, wherein
the printed wiring board has an opening portion surrounded by the region, and
the opto-electric conversion portion is disposed in the opening portion.
